(19) United States
(12) Patent Application Publication
(10) Pub. No.: US 2026/0313972 A1
(43) Pub. Date: Oct. 8, 2026

(54) DISLOCATIONS IN GAA TRANSISTORS AND THE METHODS OF FORMING THE SAME

(71) Applicant: Taiwan Semiconductor Manufacturing Co., Ltd., Hsinchu (TW)

(72) Inventors: Hui-Lin Huang, Hsinchu (TW); Cheng-Yen Wen, Hsinchu (TW); Chien-Chia Cheng, Hsinchu (TW); Ming-Hua Yu, Hsinchu (TW); Chii-Horng Li, Zhubei City (TW)

(21) Appl. No.: 19/714,915

(22) Filed: Jun. 22, 2026

Related U.S. Application Data
(63) Continuation of application No. 18/671,173, filed on May 22, 2024.
(60) Provisional application No. 63/558,961, filed on Feb. 28, 2024.

(51) Int. Cl. H10D 30/67; H10D 30/01; H10D 30/43; H10D 62/10; H10D 62/13; H10D 64/01; H10D 84/01; H10D 84/03; H10D 84/83

(52) U.S. Cl. CPC H10D 30/6735; H10D 30/014; H10D 30/43; H10D 30/6757; H10D 62/121; H10D 62/151; H10D 64/017; H10D 64/018; H10D 84/0128; H10D 84/013; H10D 84/038; H10D 84/83

(57) ABSTRACT

A method includes forming a protruding feature. The protruding feature includes
a first sacrificial nanosheet over a bulk semiconductor substrate, a first semiconductor nanosheet over the first sacrificial nanosheet, a second sacrificial nanosheet over the first semiconductor nanosheet, and a second semiconductor nanosheet over the second sacrificial nanosheet. The method further includes forming a dummy gate stack on the protruding feature, etching the protruding feature to form a recess, forming a source/drain region in the recess, wherein dislocations are formed in the source/drain region, removing the first sacrificial nanosheet and the second sacrificial nanosheet, and forming a replacement gate stack to replace the dummy gate stack.

### PRIORITY CLAIM AND CROSS-REFERENCE

This application is a continuation of U.S. patent application Ser. No. 18/671,173, filed May 22, 2024 and entitled “DISLOCATIONS IN GAA TRANSISTORS AND THE METHODS OF FORMING THE SAME,” which claims the benefit of U.S. Provisional Application No. 63/558,961, filed on Feb. 28, 2024, and entitled “DISLOCATION IN S/D EPI IN GAAFET,” which application is hereby incorporated herein by reference.

### BACKGROUND

Technological advances in Integrated Circuit (IC) materials and design have produced generations of ICs where each generation has smaller and more complex circuits than the previous generations. In the course of IC evolution, functional density (for example, the number of interconnected devices per chip area) has generally increased while geometry sizes have decreased. This scaling down process generally provides benefits by increasing production efficiency and lowering associated costs.

Such scaling down has also increased the complexity of processing and manufacturing ICs, and for these advances to be realized, similar developments in IC processing and manufacturing are needed. For example, Gate-All-Around (GAA) Transistors have been introduced to replace planar transistors. The structures of the GAA transistors and methods of fabricating the GAA transistors are being developed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-4, 5A, 5B, 6A, 6B, 7A, 7B, 8A, 8B, 9A, 9B, 10A, 10B, 11A, 11B, 12A, 12B, 13A, 13B, 14A, and 14B illustrate the views of intermediate stages in the formation of a Gate All-Around (GAA) transistor in accordance with some embodiments.

FIG. 15 through FIGS. 20A and 20B illustrate the cross-sectional views of intermediate stages in the formation of source/drain regions and some overlying features in accordance with some embodiments.

FIG. 21 illustrates a process flow for forming dielectric regions and overlying source/drain regions in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A Gate All-Around (GAA) transistor that comprises source/drain regions having dislocations is provided. In accordance with some embodiments, the processes for forming the source/drain regions are adjusted, so that dislocations are formed in the source/drain regions. Although GAA transistors are used as an example to discuss the concept of the present disclosure, the embodiments may be applied on other types of transistors including and not limited to Fin Field-Effect Transistors (FinFETs), planar transistors, and the like. Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

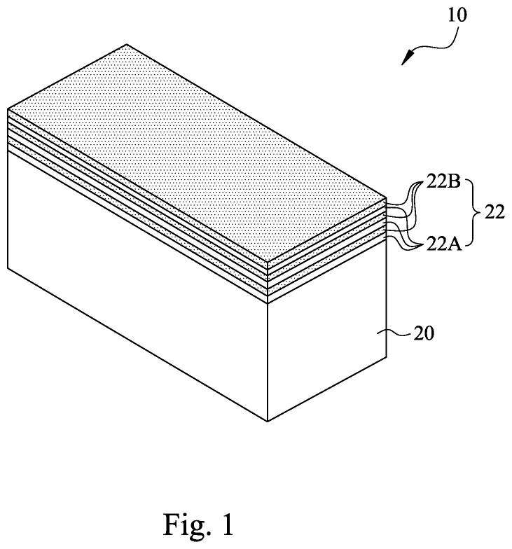

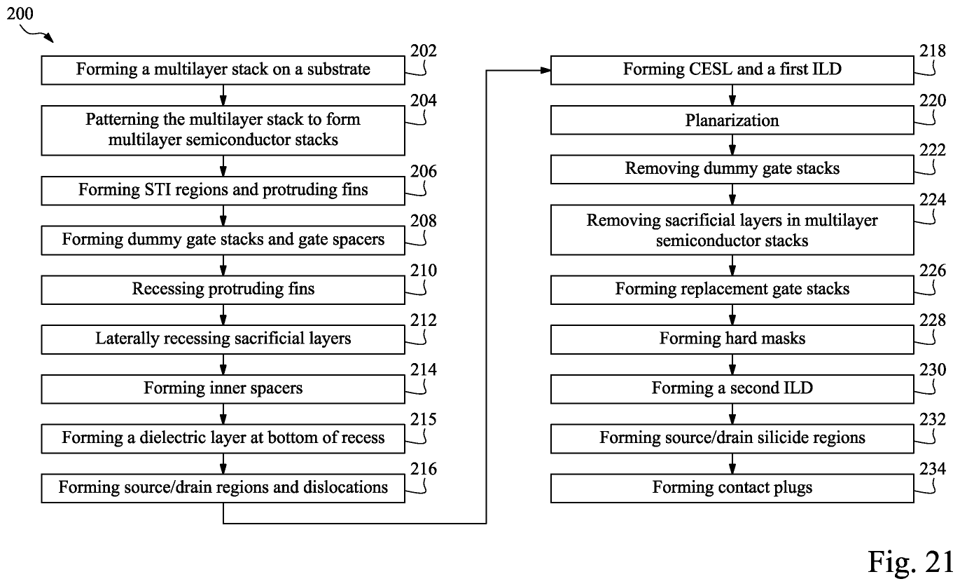

FIGS. 1-4, 5A, 5B, 6A, 6B, 7A, 7B, 8A, 8B, 9A, 9B, 10A, 10B, 11A, 11B, 12A, 12B, 13A, 13B, 14A, and 14B illustrate the cross-sectional views of intermediate stages in the formation of a GAA transistor in accordance with some embodiments of the present disclosure. The corresponding processes are also reflected schematically in the process flow shown in FIG. 21.

Referring to FIG. 1, a perspective view of wafer 10 is shown. Wafer 10 includes a multilayer structure comprising multilayer stack 22 on substrate 20. In accordance with some embodiments, substrate 20 is a semiconductor substrate, which may be a silicon substrate, a silicon germanium (SiGe) substrate, or the like, while other substrates and/or structures, such as semiconductor-on-insulator (SOI), strained SOI, silicon germanium on insulator, or the like, could be used. Substrate 20 may be doped as a p-type semiconductor, although in other embodiments, it may be doped as an n-type semiconductor.

In accordance with some embodiments, multilayer stack 22 is formed through a series of deposition processes for depositing alternating materials. The respective process is illustrated as process 202 in the process flow 200 shown in FIG. 21. In accordance with some embodiments, multilayer stack 22 comprises first layers 22A formed of a first semiconductor material and second layers 22B formed of a second semiconductor material different from the first semiconductor material.

In accordance with some embodiments, the first semiconductor material of a first layer 22A is formed of or comprises SiGe, Ge, Si, GaAs, InSb, GaSb, InAlAs, InGaAs, GaSbP, GaAsSb, or the like. In accordance with some embodiments, the deposition of first layers 22A (for example, SiGe) is through epitaxial growth, and the corresponding deposition method may be Vapor-Phase Epitaxy (VPE), Molecular Beam Epitaxy (MBE), Chemical Vapor deposition (CVD), Low Pressure CVD (LPCVD), Atomic Layer Deposition (ALD), Ultra High Vacuum CVD (UHVCVD), Reduced Pressure CVD (RPCVD), or the like. In accordance with some embodiments, the first layer 22A is formed to a first thickness in the range between about 30 Å and about 300 Å. However, any suitable thickness may be utilized while remaining within the scope of the embodiments.

Once the first layer 22A has been deposited over substrate 20, a second layer 22B is deposited over the first layer 22A. In accordance with some embodiments, the second layers 22B is formed of or comprises a second semiconductor material such as Si, SiGe, Ge, GaAs, InSb, GaSb, InAlAs, InGaAs, GaSbP, GaAsSb, combinations of these, or the like, with the second semiconductor material being different from the first semiconductor material of first layer 22A. For example, in accordance with some embodiments in which the first layer 22A is silicon germanium, the second layer 22B may be formed of silicon, or vice versa. It is appreciated that any suitable combination of materials may be utilized for first layers 22A and the second layers 22B.

In accordance with some embodiments, the second layer 22B is epitaxially grown on the first layer 22A using a deposition technique similar to that is used to form the first layer 22A. In accordance with some embodiments, the second layer 22B is formed to a similar thickness to that of the first layer 22A. The second layer 22B may also be formed to a thickness that is different from the first layer 22A. In accordance with some embodiments, the first layer 22A has thickness in the range between about 4 nm and 7 nm, while the second layer 22B has thickness in the range between about 8 nm and 12 nm, for example.

Once the second layer 22B has been formed over the first layer 22A, the deposition process is repeated to form the remaining layers in multilayer stack 22, until a desired topmost layer of multilayer stack 22 has been formed. In accordance with some embodiments, first layers 22A have thicknesses the same as or similar to each other, and second layers 22B have thicknesses the same as or similar to each other. First layers 22A may also have the same thicknesses as, or different thicknesses from, that of second layers 22B. In accordance with some embodiments, first layers 22A are removed in the subsequent processes, and are alternatively referred to as sacrificial layers 22A throughout the description. In accordance with alternative embodiments, second layers 22B are sacrificial, and are removed in the subsequent processes.

In accordance with some embodiments, there may be some pad oxide layer(s) and hard mask layer(s) (not shown) formed over multilayer stack 22. These layers are patterned, and are used for the subsequent patterning of multilayer stack 22.

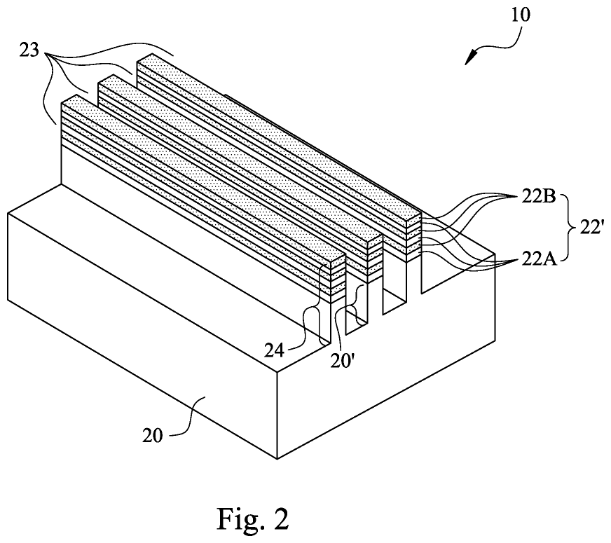

Referring to FIG. 2, multilayer stack 22 and a portion of the underlying substrate 20 are patterned in an etching process(es), so that trenches 23 are formed. The respective process is illustrated as process 204 in the process flow 200 shown in FIG. 21. Trenches 23 extend into substrate 20. The remaining portions of multilayer stacks are referred to as multilayer stacks 22′ hereinafter. Underlying multilayer stacks 22′, some portions of substrate 20 are left, and are referred to as substrate strips 20′ hereinafter. Multilayer stacks 22′ include semiconductor layers 22A and 22B. Semiconductor layers 22A are alternatively referred to as sacrificial layers, and Semiconductor layers 22B are alternatively referred to as nanostructures hereinafter. The portions of multilayer stacks 22′ and the underlying substrate strips 20′ are collectively referred to as semiconductor strips 24.

In above-illustrated embodiments, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

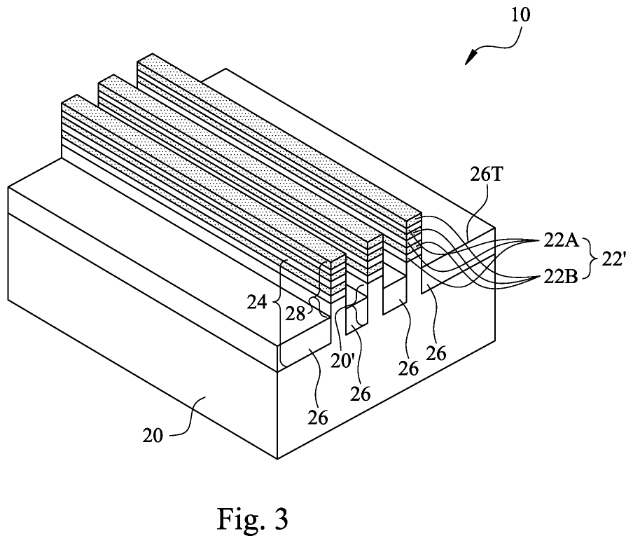

FIG. 3 illustrates the formation of isolation regions 26, which are also referred to as Shallow Trench Isolation (STI) regions throughout the description. The respective process is illustrated as process 206 in the process flow 200 shown in FIG. 21. STI regions 26 may include a liner oxide (not shown), which may be a thermal oxide formed through the thermal oxidation of a surface layer of substrate 20. The liner oxide may also be a deposited silicon oxide layer formed using, for example, ALD, High-Density Plasma Chemical Vapor Deposition (HDPCVD), CVD, or the like. STI regions 26 may also include a dielectric material over the liner oxide, wherein the dielectric material may be formed using Flowable Chemical Vapor Deposition (FCVD), spin-on coating, HDPCVD, or the like. A planarization process such as a Chemical Mechanical Polish (CMP) process or a mechanical grinding process may then be performed to level the top surface of the dielectric material, and the remaining portions of the dielectric material are STI regions 26.

STI regions 26 are then recessed, so that the top portions of semiconductor strips 24 protrude higher than the top surfaces 26T of the remaining portions of STI regions 26 to form protruding fins 28. Protruding fins 28 include multilayer stacks 22′ and the top portions of substrate strips 20′. The recessing of STI regions 26 may be performed through a dry etching process, wherein NF3 and NH3, for example, are used as the etching gases. During the etching process, plasma may be generated. Argon may also be included. In accordance with alternative embodiments of the present disclosure, the recessing of STI regions 26 is performed through a wet etching process. The etching chemical may include HF, for example.

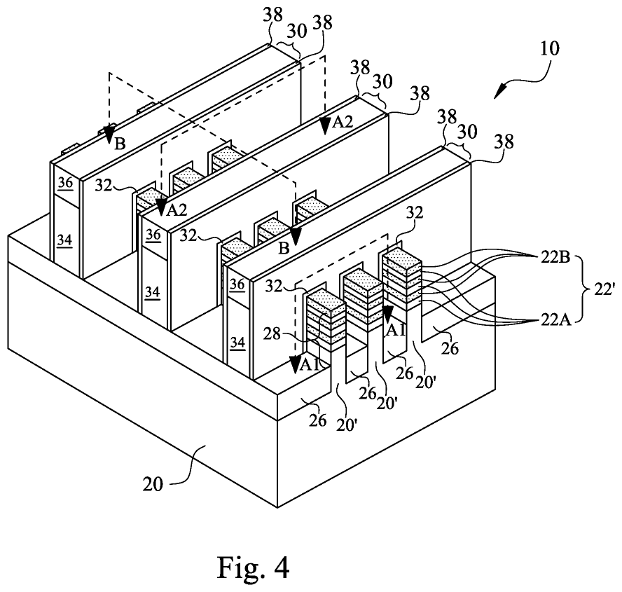

Referring to FIG. 4, dummy gate stacks 30 and gate spacers 38 are formed on the top surfaces and the sidewalls of (protruding) fins 28. The respective process is illustrated as process 208 in the process flow 200 shown in FIG. 21. Dummy gate stacks 30 may include dummy gate dielectrics 32 and dummy gate electrodes 34 over dummy gate dielectrics 32. Dummy gate dielectrics 32 may be formed by oxidizing the surface portions of protruding fins 28 to form oxide layers, or by depositing a dielectric layer such as a silicon oxide layer. Dummy gate electrodes 34 may be formed, for example, using polysilicon or amorphous silicon, and other materials such as amorphous carbon may also be used.

Each of dummy gate stacks 30 may also include one (or a plurality of) hard mask layer 36 over dummy gate electrode 34. Hard mask layers 36 may be formed of silicon nitride, silicon oxide, silicon carbo-nitride, silicon oxy-carbo nitride, or multilayers thereof. Dummy gate stacks 30 may cross over a single one or a plurality of protruding fins 28 and the STI regions 26 between protruding fins 28. Dummy gate stacks 30 also have lengthwise directions perpendicular to the lengthwise directions of protruding fins 28. The formation of dummy gate stacks 30 includes forming a dummy gate dielectric layer, depositing a dummy gate electrode layer over the dummy gate dielectric layer, depositing one or more hard mask layers, and then patterning the formed layers through a pattering process(es).

Next, gate spacers 38 are formed on the sidewalls of dummy gate stacks 30. In accordance with some embodiments of the present disclosure, gate spacers 38 are formed of a dielectric material such as silicon nitride (SiN), silicon oxide (SiO), silicon carbide (SiC), silicon dioxide (SiO2), silicon carbo-nitride (SiCN), silicon oxynitride (SiON), silicon oxy-carbo-nitride (SiOCN), or the like, and may have a single-layer structure or a multilayer structure including a plurality of dielectric layers. The formation process of gate spacers 38 may include depositing one or a plurality of dielectric layers, and then performing an anisotropic etching process(es) on the dielectric layer(s). The remaining portions of the dielectric layer(s) are gate spacers 38.

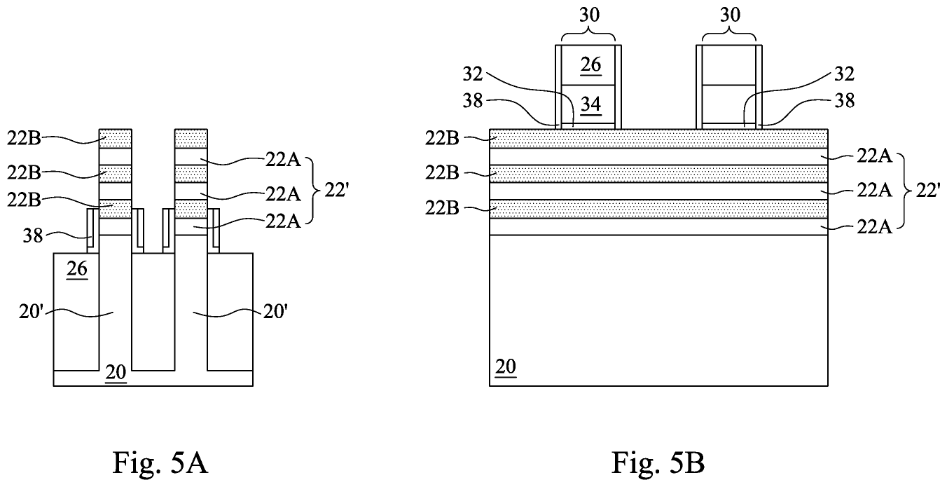

FIGS. 5A and 5B illustrate the cross-sectional views of the structure shown in FIG. 4. FIG. 5A illustrates the reference cross-section A1-A1 in FIG. 4, which cross-section cuts through the portions of protruding fins 28 not covered by gate stacks 30 and gate spacers 38, and is perpendicular to the gate-length direction. FIG. 5B illustrates the reference cross-section B-B in FIG. 4, which reference cross-section is parallel to the lengthwise directions of protruding fins 28.

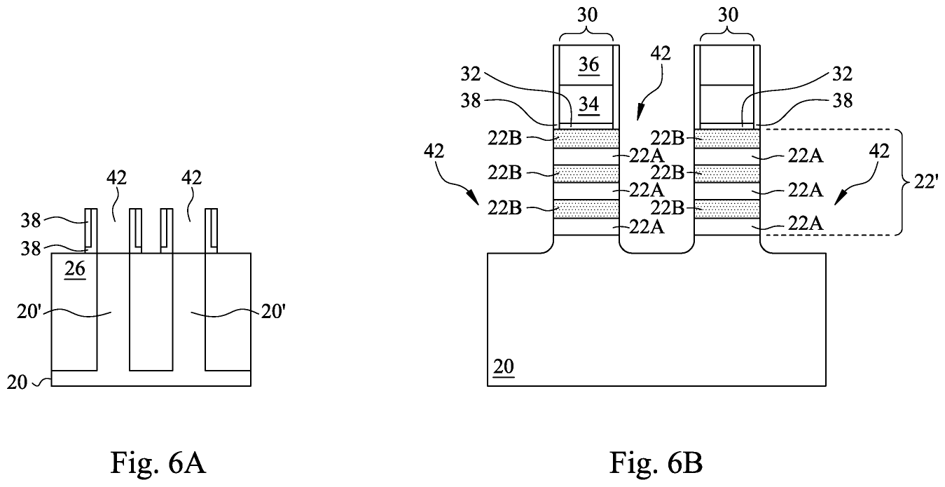

Referring to FIGS. 6A and 6B, the portions of protruding fins 28 (FIG. 4) that are not directly underlying dummy gate stacks 30 and gate spacers 38 are recessed through an etching process to form recesses 42. The respective process is illustrated as process 210 in the process flow 200 shown in FIG. 21. For example, a dry etch process may be performed using C₂F₆, CF₄, SO₂, the mixture of HBr, Cl₂, and O₂, the mixture of HBr, Cl₂, O₂, and CH₂F₂, or the like to etch multilayer semiconductor stacks 22′ and the underlying substrate strips 20′. The bottoms of recesses 42 are at least level with, or may be lower than (as shown in FIG. 6B), the bottoms of multilayer semiconductor stacks 22′. The etching may be anisotropic, so that the sidewalls of multilayer semiconductor stacks 22′ facing recesses 42 are vertical and straight, as shown in FIG. 6B.

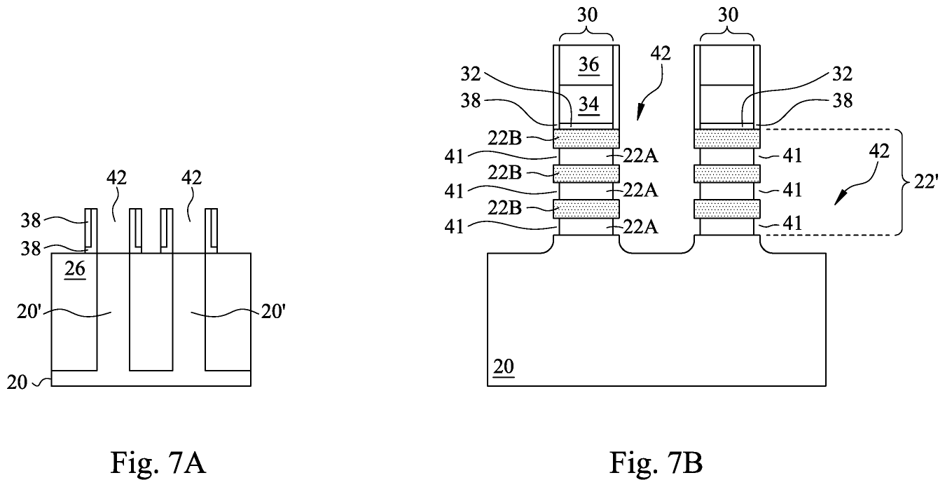

Referring to FIGS. 7A and 7B, sacrificial semiconductor layers 22A are laterally recessed to form lateral recesses 41, which are recessed from the edges of the respective overlying and underlying nanostructures 22B. The respective process is illustrated as process 212 in the process flow 200 shown in FIG. 21. The lateral recessing of sacrificial semiconductor layers 22A may be achieved through a wet etching process using an etchant that is more selective to the material (for example, silicon germanium (SiGe)) of sacrificial semiconductor layers 22A than the material (for example, silicon (Si)) of the nanostructures 22B and substrate 20. For example, in an embodiment in which sacrificial semiconductor layers 22A are formed of silicon germanium and the nanostructures 22B are formed of silicon, the wet etching process may be performed using an etchant such as hydrochloric acid (HCl). The wet etching process may be performed using a dip process, a spray process, a spin-on process, or the like.

In accordance with alternative embodiments, the lateral recessing of sacrificial semiconductor layers 22A is performed through an isotropic dry etching process or a combination of a dry etching process and a wet etching process.

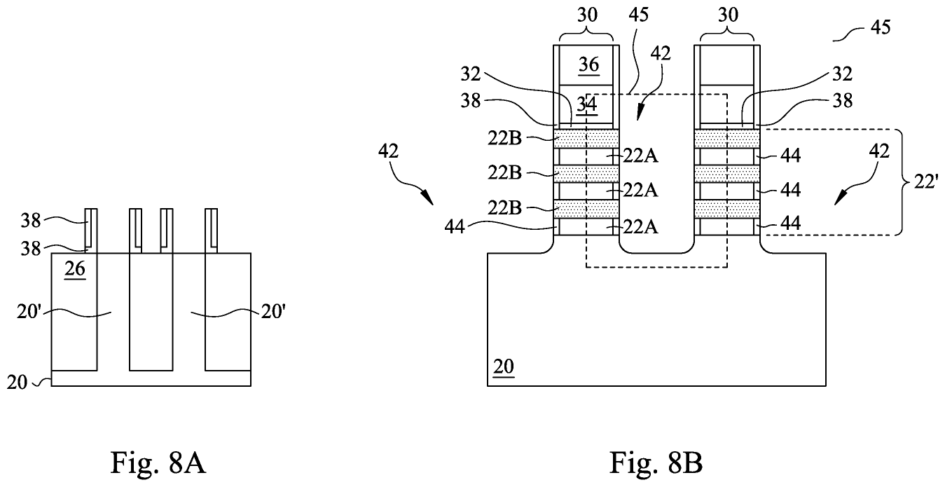

Referring to FIGS. 8A and 8B, inner spacers 44 are formed. The respective process is illustrated as process 214 in the process flow 200 shown in FIG. 21. In accordance with some embodiments, the formation of inner spacers 44 includes depositing a conformal dielectric layer, which extends into the lateral recesses 41 (FIG. 7B). Next, an etching process (also referred to as a spacer trimming process) is performed to trim the portions of the spacer layer outside of the lateral recesses 41, leaving the portions of the spacer layer in the lateral recesses 41. The remaining portions of the spacer layer are referred to as inner spacers 44.

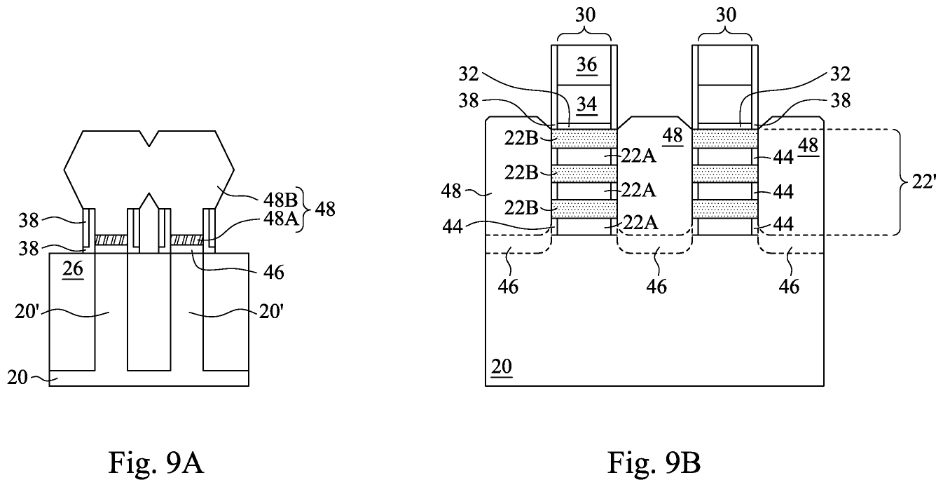

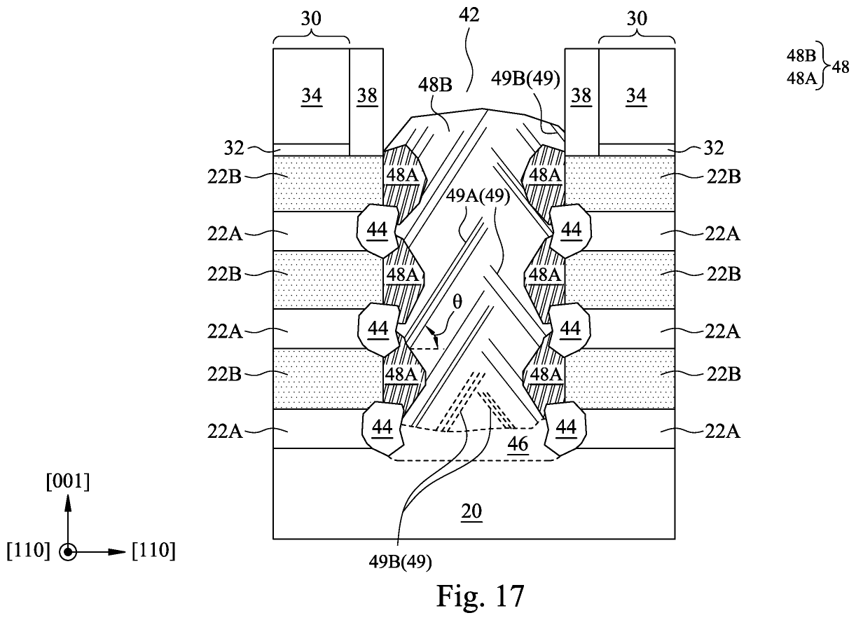

Referring to FIGS. 9A and 9B, dielectric layers 46 may be formed before the formation of source/drain regions 48. The respective process is illustrated as process 215 in the process flow 200 shown in FIG. 21. Alternatively, dielectric layers 46 are not formed. Accordingly, dielectric layers 46 are illustrated as being dashed to indicate that dielectric layers 46 may be formed or not formed. Next, epitaxial source/drain regions 48 and dislocations 49 (referring to FIG. 17) are formed in recesses 42. The respective process is illustrated as process 216 in the process flow 200 shown in FIG. 21. The details of source/drain regions 48 and dislocations 49 are illustrated in FIG. 17.

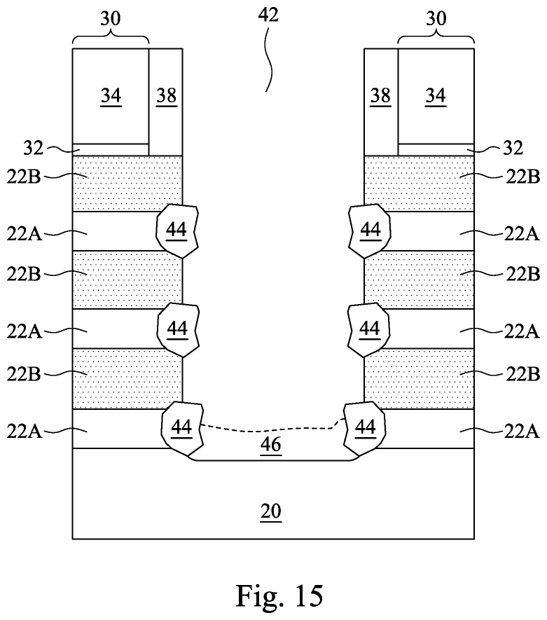

FIGS. 15-17 illustrate the details in the formation of the dielectric layers and source/drain regions (as shown in FIGS. 9A and 9B) in accordance with some embodiments. FIG. 15 illustrates the region 45 in FIG. 8B, in which recesses 42 and inner spacers 44 have been formed. Next, dielectric layer 46 is formed at the bottom of recess 42 in accordance with some embodiments. Dielectric layer 46 may comprise silicon nitride (SiN). The process gas may include silane (SiH₄), ammonia (NH₃), and the like. Dielectric layer 46 may also be formed of or comprise silicon oxide (SiO), silicon carbide (SiC), silicon oxynitride (SiON), silicon carbo-nitride (SiCN), silicon oxy carbo-nitride (SiOCN), or the like. In accordance with some embodiments, dielectric layer 46 has a multilayer structure, for example, including a conformal silicon oxide liner and a silicon nitride region on the silicon oxide liner.

In accordance with some embodiments, the formation of dielectric layer 46 includes a deposition process, followed by etching the sidewall portions of dielectric layer in recess 42, and the removal of the top portions over the top surfaces of dummy gate stacks 30 (also refer to FIG. 8B). Dielectric layer 46 may be deposited using a directional deposition process, which includes both of an anisotropic component and an isotropic component.

The sidewall portions of dielectric layer 46 in the recesses and on the sidewalls of the structure protruding higher than substrate 20 may be thinner than the bottom portion at the bottom of recess 42 and the top portions over dummy gate stack 30. An isotropic etching process is then performed to remove the thin sidewall portions. The top portions of the dielectric layer on top of dummy gate stacks 30 may be removed by using a sacrificial layer to fill recess 42 and to protect the bottom portion, and performing an etching process. In accordance with alternative embodiments, dielectric layer 46 is not formed. The dielectric layer 46 is thus illustrated as being dashed to indicate that it may be or may not be formed.

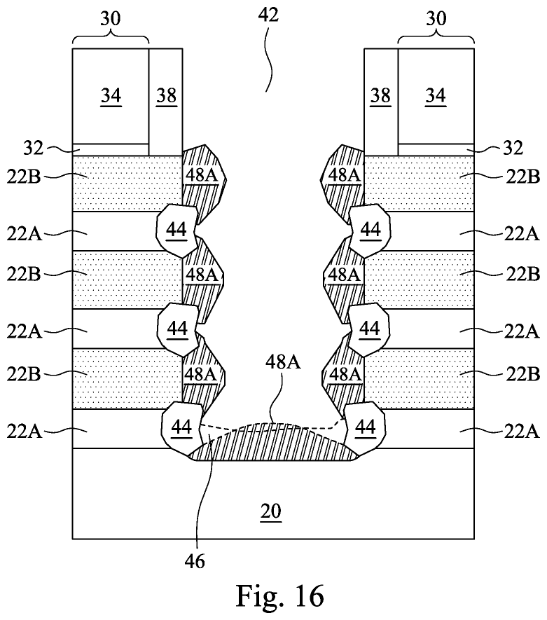

FIGS. 16 and 17 illustrate the selective formation of epitaxy regions 48 (source/drain regions) in accordance with some embodiments. Source/drain region(s) may refer to a source or a drain, individually or collectively dependent upon the context. FIG. 16 illustrates the epitaxy of semiconductor layer 48A (also referred to as layer-1 or L1) through a selective epitaxy growth process. The resulting semiconductor layer 48A is selectively grown from the sidewalls of nanostructures 22B. When there is no dielectric layer 46 formed, semiconductor layer 48A is also grown from the exposed top surface of semiconductor substrate 20. On the other hand, no portion of semiconductor layer 48A is grown from dielectric features such as inner spacers 44, gate spacers 38, and hard mask 36 (refer to FIGS. 9A and 9B).

The selective formation process may include a plurality of cycles, each including a deposition process and an etch-back process. In the deposition process, the thickness of semiconductor layer 48A is increased, while in the etch-back process, the thickness of semiconductor layer 48A is reduced. The plurality of cycles are also referred to as deposition-and-etch cycles.

When the source/drain region is an n-type region of an n-type transistor, semiconductor layer 48A may comprise silicon or SiC (and may or may not comprise a small amount of germanium) and an n-type dopant such as As, P, Sb, or the like, or combinations thereof. For example, semiconductor layer 48A may comprise SiAs, SiP, SiCP, SiAsP, SiSb, or the like. The semiconductor layer 48A may have an n-type dopant concentration in a range between about 1E20/cm³ and³ about 2E21/cm³. The thickness of semiconductor layer 48A may be smaller than about 10 nm.

In the deposition, the process gases for forming the n-type semiconductor layer 48A may include SiH₄, dicholorosilane (DCS), HCl, GeH₄, PH₃, or the like. The wafer temperature may be in the range between about 500° C. and about 850° C., the chamber pressure may be in the range between about 4 torr and about 300 torr.

When the source/drain region is a p-type region of a p-type transistor, semiconductor layer 48A may comprise silicon, SiGe, or Ge, and further includes a p-type dopant such as boron, indium, or combinations thereof. For example, semiconductor layer 48A may comprise SiGeB, GeB, or the like. The semiconductor layer 48A may have a p-type dopant concentration in a range lower than about 5E20/cm³, such as in a range between about 1E20/cm³ and³ about 5E20/cm³. The thickness of semiconductor layer 48A may be smaller than about 10 nm.

In the deposition of the p-type semiconductor layer 48A, the process gases may include SiH₄, DCS, HCl, GeH₄, BH₃, BCl₃, or the like. The wafer temperature may be in the range between about 400° C. and about 850° C., the chamber pressure may be in the range between about 4 torr and about 300 torr.

In accordance with some embodiments, as discussed in the preceding paragraphs, the process gases may include an etching gas for etching semiconductor layer 48A. For example, the etching gas may include HCl. The etching gas helps to remove the deposited semiconductor layer 48A on dielectric features such as inner spacers 44, gate spacers 38, hard masks 36, and dielectric layer 46, if any. In order to form high-quality semiconductor layer 48A, the deposition rate of semiconductor layer 48A is kept low, for example, lower than about 10 Å/minute.

After the deposition of one layer of semiconductor layer 48A, an etch-back process is performed to etch-back semiconductor layer 48A. This helps to remove any deposited semiconductor on dielectric features. In accordance with some embodiments, if any dislocation is formed in semiconductor layer 48A, the portions of semiconductor layer 48A having the dislocations are etched. Accordingly, the semiconductor layer 48A remaining after the etch-back process does not include dislocations therein. As a result of the etch-back process and the low growth rate, semiconductor layer 48A may be free from dislocations therein, or may have a low number of dislocations.

FIG. 17 illustrates the epitaxy growth of semiconductor layer 48B (also referred to as semiconductor layer-2 or L2) and the dislocations 49 therein. The resulting semiconductor layer 48B is grown from, and is different from semiconductor layer 48A. For example, semiconductor layer 48B may be deposited as having an element (such as arsenic (As)) that is not in semiconductor layer 48A, or vice versa. Semiconductor layers 48A and 48B may have a same element (such as Si) but have different percentages of the element(s). The deposition process may be selective, so that no semiconductor layer 48B is directly grown from dielectric features such as inner spacers 44, gate spacers 38, and hard mask 36.

It is appreciated, however, as shown in FIG. 16, some dielectric features such as inner spacers 44 and dielectric layer 46 may still have surfaces exposed to recess 42, and semiconductor layer 48B may grow from semiconductor layer 48A and grown to the dielectric features, so that semiconductor layer 48B may be in contact with the dielectric features. When the deposition of semiconductor layer 48B is ended, the top surface of semiconductor layer 48B may be higher than the top surface of the topmost nanostructure 22B.

When the source/drain region 48 is an n-type region of an n-type transistor, semiconductor layer 48B may comprise silicon or SiC (and may or may not comprises a small amount of germanium) and an n-type dopant such as phosphorous. For example, semiconductor layer 48B may comprise, SiP, SiCP, or the like, and may be free from n-type dopants such as As, Sb, and the like (which are doped in semiconductor layer 48B). The semiconductor layer 48B may have an n-type dopant concentration higher than the n-type dopant concentration in semiconductor layer 48A. For example, the n-type dopant concentration in semiconductor layer 48B may be in a range between about 5E20/cm³ and about 5E21/cm³.

In the deposition of the n-type semiconductor layer 48B, the process gases may include SiH₄, DCS, HCl, GeH₄, PH₃, or the like. The wafer temperature may be in the range between about 500° C. and about 850° C., the chamber pressure may be in the range between about 4 torr and about 300 torr.

When the source/drain region is a p-type region of a p-type transistor, semiconductor layer 48B may comprise SiGe or Ge, and may further include a p-type dopant such as boron, indium, or combinations thereof. For example, semiconductor layer 48B may comprise SiGeB, GeB, or the like. The germanium atomic percentage may be greater than the germanium atomic percentage in semiconductor layer 48A, for example, with a difference being greater than about 20 percent or 30 percent. For example, the germanium atomic percentage in semiconductor layer 48B may be in the range between about 50 percent and about 60 percent. The p-type dopant concentration in semiconductor layer 48B may be higher than the p-type dopant concentration in semiconductor layer 48A. For example, the p-type dopant concentration in semiconductor layer 48B may be in a range between about 7E20/cm³ and³ about 1E21/cm³.

In the deposition of the p-type semiconductor layer 48B, the process gases may include SiH₄, DCS, HCl, GeH₄, BH₃, BCl₃, or the like. The wafer temperature may be in the range between about 400° C. and about 850° C., the chamber pressure may be in the range between about 4 torr and about 300 torr.

In accordance with some embodiments, the deposition process gas may further include an etching gas such as HCl, so that the semiconductor layer 48B is not grown on gate spacers 38 and hard masks 36 (FIG. 8B).

During the formation of semiconductor layer 48B, dislocations 49 (including dislocations 49A and 49B) are formed and grown along with the deposition of semiconductor layer 48B. The length of dislocations 49 may be in the range between about 1 nm and about 70 nm. The total count of dislocations 49 may be from 1 to several hundreds. The dislocations may include the ones with opposite slopes, for example, the ones in the bottom-left to top-right direction, and the ones in the bottom-right to top-left direction.

In order to form dislocations 49, the formation process of semiconductor layer 48B is adjusted to be different from that of semiconductor layer 48A. In accordance with some embodiments, the growth of semiconductor layer 48B is continuously performed without etch-back process therein. Alternatively stated, the formation of semiconductor layer 48B may be a continuous growth process until the top surface of semiconductor layer 48B is higher than the top surface of the top semiconductor nanostructure 22B, without etch-back process therein. Accordingly, during the growth, the dislocations 49 have a chance to further grow, rather than be removed in the etch-back process. If etch-back is performed, semiconductor layer 48B may not have dislocations therein.

It is appreciated that when the growth rate of semiconductor layer 48B is low, dislocations may not be able to be formed, even if no etch-back is performed in the formation of semiconductor layer 48B. To ensure the formation of dislocations 49, the growth rate of semiconductor layer 48B is increased. In accordance with some embodiments, the deposition rate of semiconductor layer 48B is relatively high, for example, higher than about 20 Å/minute, and may be in the range between about 20 Å/minute and about 500 Å/minute. In accordance with some embodiments, to increase the deposition rate of semiconductor layer 48B, process conditions are adjusted. For example, the pressure of the deposition chamber, the flow rate (and/or the partial pressure) of the precursors (such as the silicon-containing precursor and/or the dopant-containing precursor), the wafer temperature, and/or the like may be increased.

In accordance with some embodiments, the partial pressure P2 of the silicon-containing gas in the formation of semiconductor layer 48B is higher than the partial pressure P1 of the silicon-containing gas in the formation of semiconductor layer 48A. For example, ratio P2/P1 is higher than 1.o, and may be in the range between about 1.1 and about 5 in accordance with some embodiments.

In accordance with some embodiments, the wafer temperature T2 in the formation of semiconductor layer 48B is higher than the temperature T1 in the formation of semiconductor layer 48A. For example, temperature difference (T2−T1) may be greater than about 25° C., and may be in the range between about 5° C. and about 250° C., or in the range between about 100° C. and about 250° C. in accordance with some embodiments.

In accordance with some embodiments, the flow rate FR2 of the silicon-containing gas in the formation of semiconductor layer 48B is higher than the pressure flow rate FR1 of the silicon-containing gas in the formation of semiconductor layer 48A. For example, ratio FR2/FR1 is higher than 1.o, and may be in the range between about 1and about 5 in accordance with some embodiments.

In accordance with some embodiments, the growth (deposition) rate GR2 (the increase in thickness per unit time) of semiconductor layer 48B is higher than the growth rate GR1 (during the deposition processes of the deposition-and-etch back cycles) of semiconductor layer 48A. For example, the ratio GR2/GR1 is greater than 1.0, and may be in the range between about 2 and about 10 in accordance with some embodiments.

In accordance with some embodiments, to find the optimum ranges of process conditions for generating dislocations without causing other problems (such as the growth of semiconductor on dielectric materials), a plurality of sample wafers will be formed having the identical structures as in FIGS. 8B and 15. Source/drain regions 48 (including layers 48A and 48B) are grown in the sample wafers using different combinations of process conditions including, and not limited to, different growth rates, different wafer temperatures, different chamber pressures, and different flow rates. The resulting wafers are examined, for example, using Transmission Electron Microscopy (TEM) to determine whether dislocations are formed or not, and to find the number of dislocations. The process conditions that will result in the desirable dislocations are used for the manufacturing of the wafers.

Dislocations 49 may include the dislocations 49A, which starts to be formed when the growth of semiconductor layer 48B is started. Accordingly, the beginning ends of dislocations 49A may be at the interfaces of semiconductor layers 48A and 48B. Semiconductor layer 48A, on the other hand, may not have dislocations therein. Alternatively, both of semiconductor layers 48A and 48B have dislocations 49 therein, while the number of dislocations in semiconductor layer 48A is significantly lower (for example, fewer than 5 percent) of the number of dislocations 49 in semiconductor layer 48B. In accordance with these embodiments, some dislocations 49 starts to be formed in semiconductor layer 48A, while other dislocations 49 start to be formed from the interfaces of semiconductor layers 48A and 48B.

Dislocations 49 may further include the dislocations 49B, which have their beginning ends at the surfaces of dielectric features such as dielectric layer 46, inner spacers 44, gate spacers 38, and the like. Each dislocation 49B thus may have an end contacting a dielectric feature.

In accordance with alternative embodiments, rather than starting to adopt the process conditions for generating dislocations 49 (which process conditions include no etch-back process and higher growth rate), the process conditions for generating dislocations 49 may be adopted during the formation of semiconductor layer 48A, or during the formation of semiconductor layer 48B. For example, the formation of a lower part of semiconductor layer 48A (or 48B) may adopt etch-back process and/or lower wafer temperature, so that no dislocation is formed. The formation of an upper part of semiconductor layer 48A (or 48B), however, adopts different process conditions such as no etch-back process and higher wafer temperatures/flow rates, so that dislocations 49 starts to be formed when the upper part of semiconductor layer 48A (or 48B) is deposited.

In accordance with some embodiments, substrate 20 has a top surface orientation, and a horizontal direction (for example, toward right) in [110] directions. In accordance with some embodiments, dislocations 49 grow in the [111] directions. The tilt angle θ of dislocations 49 may be in the range between about 20 degrees and about 70 degrees, and may be about 54.7 degrees.

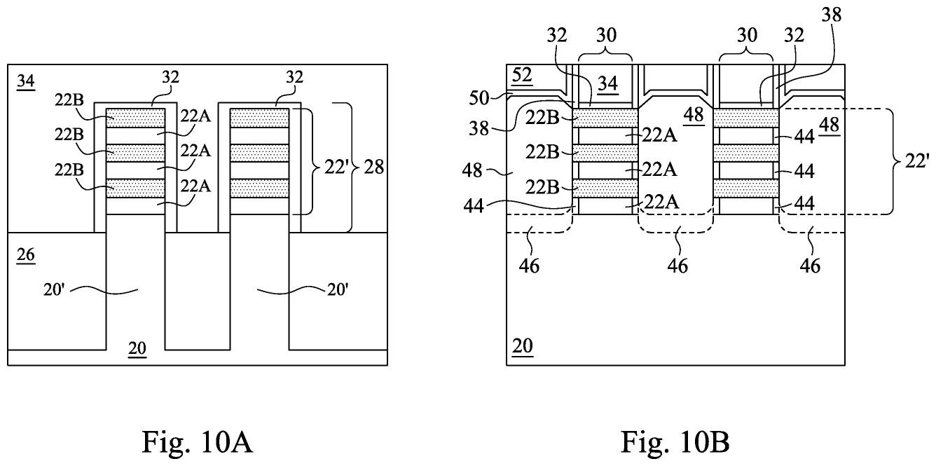

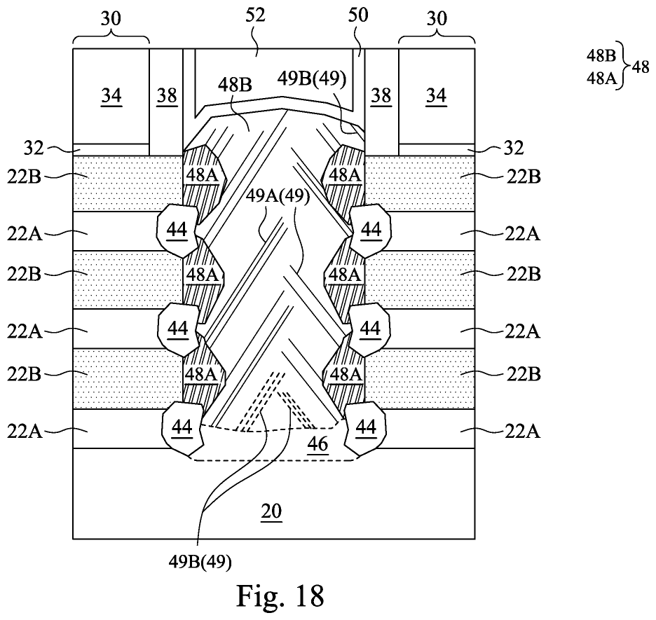

FIGS. 10A and 10B illustrate the cross-sectional views of the structure after the formation of Contact Etch Stop Layer (CESL) 50 and Inter-Layer Dielectric (ILD) 52. The respective process is illustrated as process 218 in the process flow 200 shown in FIG. 21. The corresponding structure is also shown in FIG. 18. CESL 50 may be formed of silicon oxide, silicon nitride, silicon carbo-nitride, or the like, and may be formed using CVD, ALD, or the like. ILD 52 may include a dielectric material formed using, for example, FCVD, spin-on coating, CVD, or any other suitable deposition method. ILD 52 may be formed of an oxygen-containing dielectric material, which may be a silicon-oxide based material formed using Tetra Ethyl Ortho Silicate (TEOS) as a precursor, Phospho-Silicate Glass (PSG), Boro-Silicate Glass (BSG), Boron-Doped Phospho-Silicate Glass (BPSG), Undoped Silicate Glass (USG), or the like.

CESL 50 and ILD 52 are planarized through a planarization process such as a CMP process or a mechanical grinding process. The respective process is illustrated as process 220 in the process flow 200 shown in FIG. 21. In accordance with some embodiments, the planarization process may remove hard masks 36 to reveal dummy gate electrodes 34, as shown in FIG. 10A. In accordance with alternative embodiments, the planarization process may reveal, and is stopped on, hard masks 36. In accordance with some embodiments, after the planarization process, the top surfaces of dummy gate electrodes 34 (or hard masks 36), gate spacers 38, and ILD 52 are level within process variations.

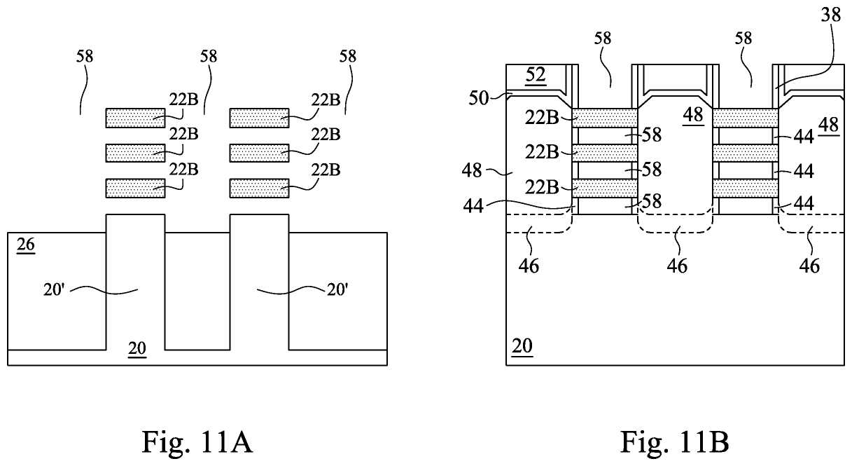

Next, dummy gate electrodes 34 and dummy gate dielectrics 32 (and hard masks 36, if remaining) are removed in one or more etching processes, so that recesses 58 are formed, as shown in FIGS. 11A and 11B. The respective process is illustrated as process 222 in the process flow 200 shown in FIG. 21. In accordance with some embodiments, dummy gate electrodes 34 and dummy gate dielectrics 32 are removed through an anisotropic dry etch process(es). For example, the etching process may be performed using reaction gas(es) that selectively etch dummy gate electrodes 34 and dummy gate dielectrics 32 at faster rates than ILD 52. Each recess 58 exposes and/or overlies portions of multilayer stacks 22′, which include the future channel regions in subsequently completed transistors.

Sacrificial layers 22A are then removed to extend recesses 58 between nanostructures 22B. The respective process is illustrated as process 224 in the process flow 200 shown in FIG. 21. Sacrificial layers 22A may be removed by performing an isotropic etching process such as a wet etching process using etchants which are selective to the materials of sacrificial layers 22A, while nanostructures 22B, substrate 20, and STI regions 26 remain relatively un-etched as compared to sacrificial layers 22A. In accordance with some embodiments in which sacrificial layers 22A include, for example, SiGe, and nanostructures 22B include, for example, Si or SiC, tetra methyl ammonium hydroxide (TMAH), ammonium hydroxide (NH₄OH), or the like may be used to remove sacrificial layers 22A.

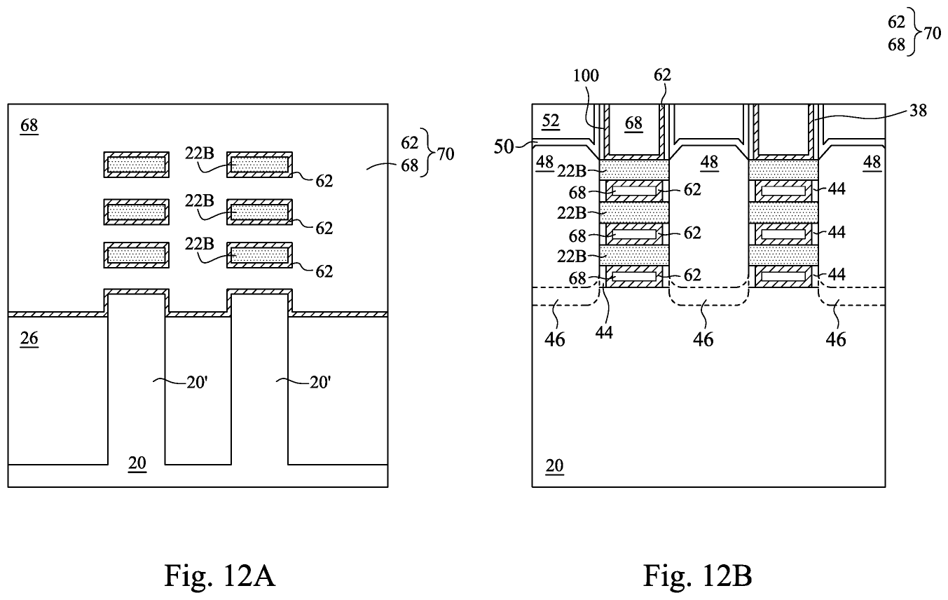

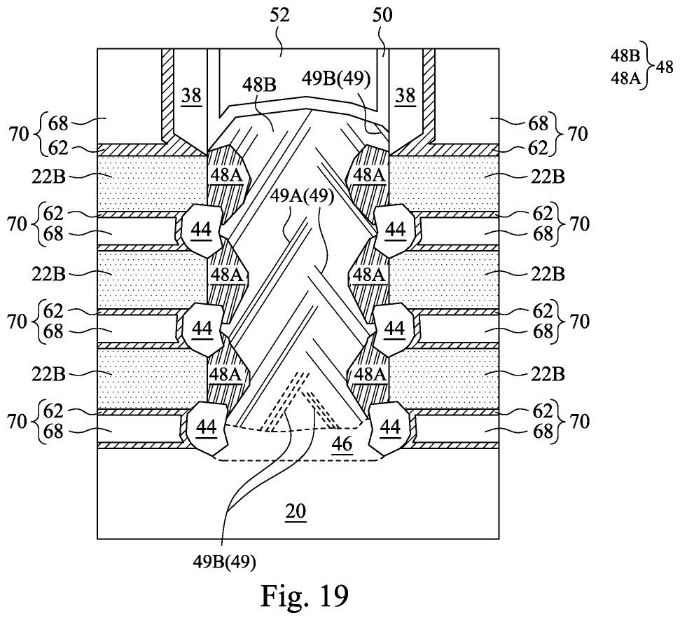

Referring to FIGS. 12A and 12B, gate dielectrics 62 and gate electrodes 68 are formed, hence forming replacement gate stacks 70. The respective process is illustrated as process 226 in the process flow 200 shown in FIG. 21. The corresponding structure is also shown in FIG. 19. In accordance with some embodiments, each of gate dielectric 62 includes an interfacial layer and a high-k dielectric layer on the interfacial layer. The interfacial layer may be formed of or comprises silicon oxide, which may be deposited through a conformal deposition process such as ALD or CVD, or through an oxidation process. In accordance with some embodiments, the high-k dielectric layers comprise one or more dielectric layers. For example, the high-k dielectric layer(s) may include a metal oxide or a silicate of hafnium, aluminum, zirconium, lanthanum, manganese, barium, titanium, lead, and combinations thereof.

Gate electrodes 68 are also formed. In the formation, conductive layers are first formed on the high-k dielectric layer, and the remaining portions of recesses 58 are filled. Gate electrodes 68 may include a metal-containing material such as TiN, TaN, TiAl, TiAlC, cobalt, ruthenium, aluminum, tungsten, combinations thereof, and/or multilayers thereof. For example, gate electrodes 68 may comprise any number of layers, any number of work function layers, and possibly a filling material. Gate dielectrics 62 and gate electrodes 68 also fill the spaces between adjacent ones of nanostructures 22B, and fill the spaces between the bottom ones of nanostructures 22B and the underlying substrate strips 20′. After the filling of recesses 58, a planarization process such as a CMP process or a mechanical grinding process is performed to remove the excess portions of the gate dielectrics and the material of gate electrodes 68, which excess portions are over the top surface of ILD 52. Gate electrodes 68 and gate dielectrics 62 are collectively referred to as gate stacks 70 of the resulting transistors.

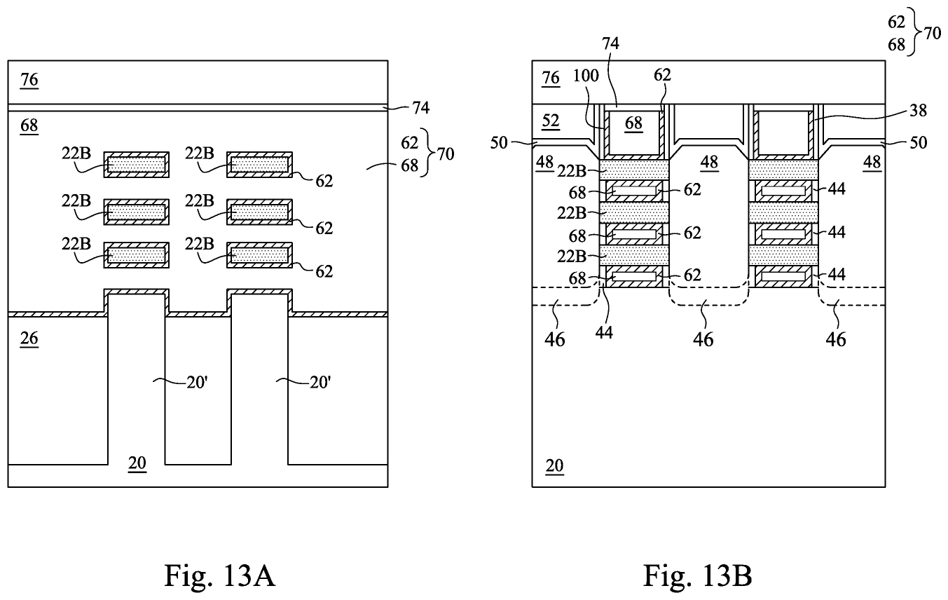

In the processes shown in FIGS. 13A and 13B, gate stacks 70 are recessed, so that recesses are formed directly over gate stacks 70 and between opposing portions of gate spacers 38. A gate mask 74 comprising one or more layers of dielectric material, such as silicon nitride, silicon oxynitride, or the like, is filled in each of the recesses, followed by a planarization process to remove excess portions of the dielectric material extending over ILD 52. The respective process is illustrated as process 228 in the process flow 200 shown in FIG. 21.

As further illustrated by FIGS. 13A and 13B, ILD 76 is deposited over ILD 52 and over gate masks 74. The respective process is illustrated as process 230 in the process flow 200 shown in FIG. 21. An etch stop layer (not shown) may be (or may not be) deposited before the formation of ILD 76. In accordance with some embodiments, ILD 76 is formed through FCVD, CVD, PECVD, or the like. ILD 76 is formed of a dielectric material, which may be selected from silicon oxide, PSG, BSG, BPSG, USG, or the like.

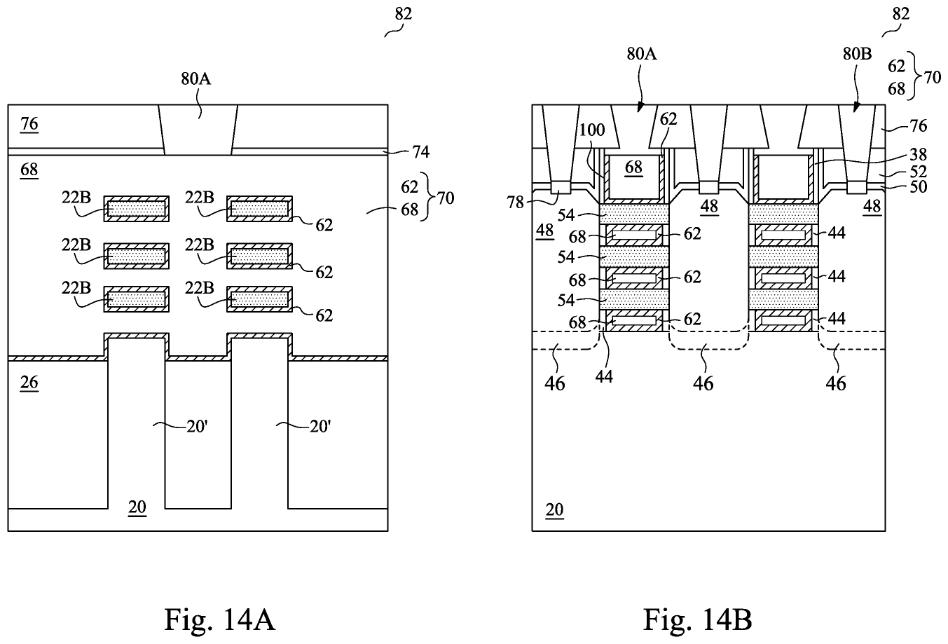

In FIGS. 14A and 14B, ILD 76, ILD 52, CESL 50, and gate masks 74 are etched to form recesses (occupied by contact plugs 80A and 80B) exposing surfaces of source/drain regions 48 and/or gate stacks 70. The recesses may be formed through etching using an anisotropic etching process, such as RIE, NBE, or the like. Although FIG. 14B illustrates that contact plugs 80A and 80B are in a same cross-section, in various embodiments, contact plugs 80A and 80B may be formed in different cross-sections, thereby reducing the risk of shorting with each other.

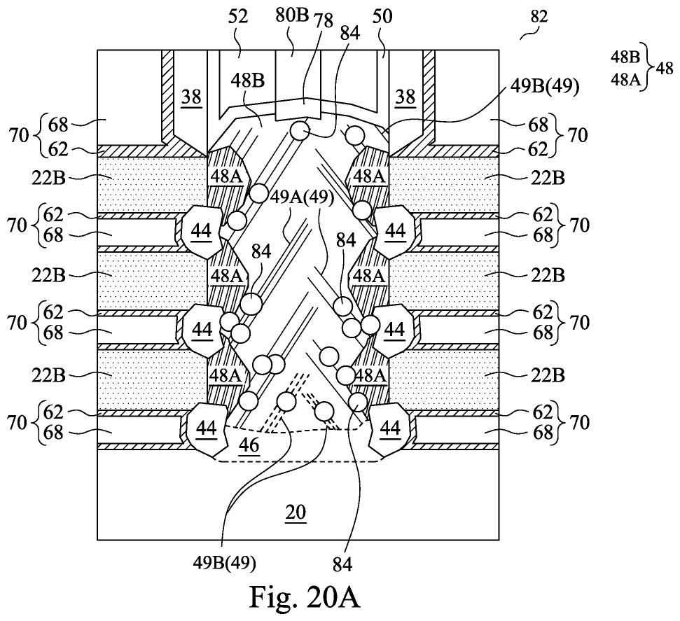

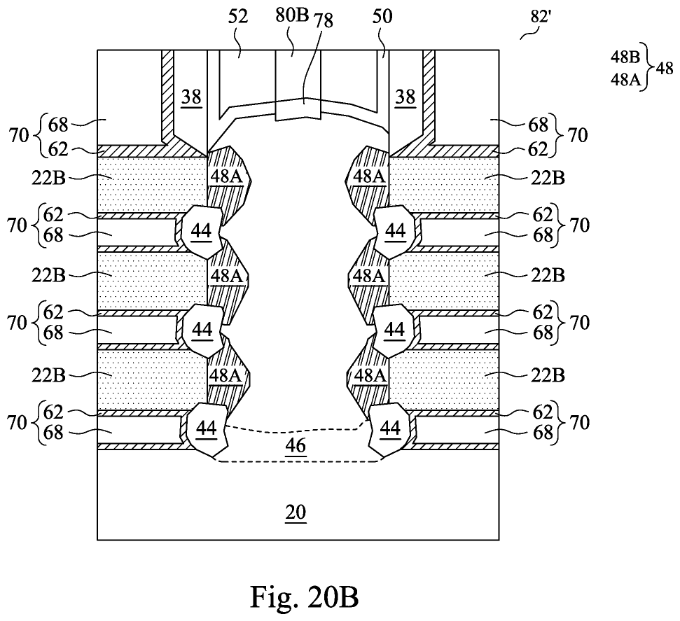

After the recesses are formed, silicide regions 78 are formed over source/drain regions 48. The respective process is illustrated as process 232 in the process flow 200 shown in FIG. 21. Contact plugs 80B are then formed over silicide regions 78. Also, contacts 80A (may also be referred to as gate contact plugs) are also formed in the recesses, and are over and contacting gate electrodes 68. The respective process is illustrated as process 234 in the process flow 200 shown in FIG. 21. The corresponding structure is also shown in FIG. 20A. Transistor 82 is thus formed. It is noted that the details of the source/drain regions 48 and dislocations 49 are not shown in FIGS. 14A and 14B, and the details may be found referring to FIG. 20A.

Due to the formation of dislocations 49, the metals used in the processes following the formation of source/drain regions 48 have a higher chance to diffuse to and through dislocations 49, thus metal ions have higher concentrations at dislocations 49 than in the parts of source/drain regions 48 neighboring the dislocations 49. For example, FIG. 20A schematically illustrates the concentrated metal ions 84 along and at dislocations 49, which metal ions 84 may include the ions of an alkali metal(s) (such as lithium, sodium, potassium), tungsten, cobalt, nickel, titanium, tantalum, or the like. Accordingly, the concentrated metal ions 84 have concentrations higher than the parts of the source/drain regions 48 apart from the dislocations 49. The diffusion of the metal ions 84 may occur during the subsequent formation (such as the deposition and the CMP) of contact plugs 80B. The concentration of the metal ions 84 may be observed using elemental analysis such as Electron Dispersive X-ray Spectroscopy (EDX) or Atom Probe Tomography (APT).

FIG. 20B illustrates parts of GAA transistor 82′ in accordance with some embodiments. GAA transistor 82′ may have essentially the same structure as, and formed using essentially the same processes as, the GAA transistor 82 in FIG. 20A. GAA transistors 82′ and 82 may be formed in the same device die and on the same semiconductor substrate 20. The source/drain region 48 of GAA transistor 82′ is free from dislocations, so that GAA transistor 82′ has lower drive current than GAA transistor 82 to suit to customized design requirement.

In accordance with some embodiments, most of the formation processes of GAA transistor 82′ may be shared with GAA transistor 82, except for the formation of source/drain regions 48. The formation of the source/drain regions 48 of GAA transistor 82 is tuned for forming dislocations, while the formation of the source/drain regions 48 of GAA transistor 82′ is tuned to be free from dislocations. In accordance with some embodiments, the semiconductor layers 48A of GAA transistors 82 and 82′ share a common formation process(es), while the semiconductor layers 48B of GAA transistors 82 and 82′ are formed by separate processes, so that GAA transistor 82 has dislocations 49, and the GAA transistor 82′ are free from dislocations.

The embodiments of the present disclosure have some advantageous features. By adjusting process conditions, dislocations may be formed in source/drain regions. The dislocations result in the increased stress to the channel regions. The currents of the resulting GAA transistors are thus increased.

In accordance with some embodiments of the present disclosure, a method comprises forming a protruding feature comprising a first sacrificial nanosheet over a bulk semiconductor substrate; a first semiconductor nanosheet over the first sacrificial nanosheet; a second sacrificial nanosheet over the first semiconductor nanosheet; and a second semiconductor nanosheet over the second sacrificial nanosheet; forming a dummy gate stack on the protruding feature; etching the protruding feature to form a recess; forming a source/drain region in the recess, wherein dislocations are formed in the source/drain region; removing the first sacrificial nanosheet and the second sacrificial nanosheet; and forming a replacement gate stack to replace the dummy gate stack.

In an embodiment, the method further comprises, before the source/drain region is formed in the recess, forming a dielectric layer at a bottom of the recess. In an embodiment, some of the dislocations are formed starting from the dielectric layer. In an embodiment, the forming the source/drain region comprises epitaxially growing a first semiconductor layer; and epitaxially growing a second semiconductor layer different from the first semiconductor layer, wherein the dislocations start to grow when the second semiconductor layer is grown.

In an embodiment, the growing the first semiconductor layer comprises a plurality of cycles, each comprising depositing a layer of the first semiconductor layer; and etching back the layer of the first semiconductor layer, and wherein the growing the second semiconductor layer is a continuous process that ends after the second semiconductor layer has a first top surface higher than a second top surface of the second semiconductor nanosheet. In an embodiment, the growing the second semiconductor layer is performed without etch-back process therein. In an embodiment, the growing the first semiconductor layer is performed at a first wafer temperature, and the growing the second semiconductor layer is performed at a second wafer temperature higher than the first wafer temperature.

In an embodiment, the growing the first semiconductor layer is performed with a first flow rate of a silicon-containing precursor, and the growing the second semiconductor layer is performed with a second flow rate of the silicon-containing precursor, and wherein the second flow rate is higher than the first flow rate. In an embodiment, the growing the first semiconductor layer is performed with a first partial pressure of a silicon-containing precursor, and the growing the second semiconductor layer is performed with a second partial pressure of the silicon-containing precursor, and the second partial pressure is higher than the first partial pressure. In an embodiment, all of the dislocations in the source/drain region are spaced apart from all semiconductor nanosheets in the protruding feature.

In accordance with some embodiments of the present disclosure, a device comprises a first semiconductor nanostructure; a second semiconductor nanostructure over the first semiconductor nanostructure; a gate stack comprising a portion between the first semiconductor nanostructure and the second semiconductor nanostructure; a source/drain region aside of and joined to the first semiconductor nanostructure and the second semiconductor nanostructure, wherein the first semiconductor nanostructure, the second semiconductor nanostructure, the gate stack, and the source/drain region form parts of a transistor; and a first dislocation in the source/drain region.

In an embodiment, the device further comprises a second dislocation in the source/drain region and parallel to the first dislocation. In an embodiment, the device further comprises metal ions concentrated at the first dislocation, wherein the metal ions have a higher metal ion concentration at the first dislocation than surrounding parts of the source/drain region. In an embodiment, the device further comprises a dielectric layer underlying and contacting the source/drain region, wherein the first dislocation has an end contacting the dielectric layer.

In an embodiment, the first dislocation is spaced apart from all semiconductor nanostructures in the transistor. In an embodiment, the source/drain region comprises a first semiconductor layer contacting the first semiconductor nanostructure; and a second semiconductor layer different from the first semiconductor layer, wherein an end of the first dislocation is at an interface between the first semiconductor layer and the second semiconductor layer. In an embodiment, the device further comprises an inner spacer contacting the portion of the gate stack, wherein the first dislocation has an end contacting the inner spacer.

In accordance with some embodiments of the present disclosure, a device comprises a first plurality of semiconductor nanostructures, wherein upper ones of the first plurality of semiconductor nanostructures overlap respective lower ones of the first plurality of semiconductor nanostructures; a first gate stack comprising portions between the first plurality of semiconductor nanostructures; a second plurality of semiconductor nanostructures, wherein upper ones of the second plurality of semiconductor nanostructures overlap respective lower ones of the second plurality of semiconductor nanostructures; a second gate stack comprising portions between the second plurality of semiconductor nanostructures; a source/drain region between the first plurality of semiconductor nanostructures and the second plurality of semiconductor nanostructures; a first plurality of dislocations in the source/drain region and parallel to each other, wherein the first plurality of dislocations comprise first lower ends close to the first plurality of semiconductor nanostructures; and a second plurality of dislocations in the source/drain region and parallel to each other, wherein the second plurality of dislocations comprise second lower ends close to the second plurality of semiconductor nanostructures.

In an embodiment, the first plurality of dislocations are spaced apart from the first plurality of semiconductor nanostructures by a portion of the source/drain region. In an embodiment, the portion of the source/drain region separating the first plurality of dislocations apart from the first plurality of semiconductor nanostructures has a different composition than the portions of the source/drain region comprising the dislocations therein.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a semiconductor region over a bulk semiconductor substrate;
forming a dummy gate stack over the semiconductor region;
etching the semiconductor region to form a recess;
performing a first epitaxy process to form a first semiconductor layer;
performing a second epitaxy process to form a second semiconductor layer over the first semiconductor layer, wherein dislocations are formed in the second semiconductor layer, and wherein the first semiconductor layer and the second semiconductor layer collectively form a source/drain region; and
forming a replacement gate stack to replace the dummy gate stack.

2. The method of claim 1, wherein the dislocations comprise ends at an interface between the first semiconductor layer and the second semiconductor layer.

3. The method of claim 1, wherein the first semiconductor layer is free from dislocations therein.

4. The method of claim 1, wherein the first semiconductor layer are formed by processes comprising:
depositing a layer of the first semiconductor layer comprising additional dislocations; and
etching back the layer of the first semiconductor layer until the additional dislocations are removed.

5. The method of claim 4, wherein the second epitaxy process is performed until the second semiconductor layer has a top surface higher than an interface between the semiconductor region and the dummy gate stack.

6. The method of claim 4, wherein the second epitaxy process is performed without etch-back therein.

7. The method of claim 1, wherein the semiconductor region comprises:
a first sacrificial nanosheet;
a first semiconductor nanosheet over the first sacrificial nanosheet;
a second sacrificial nanosheet over the first semiconductor nanosheet; and
a second semiconductor nanosheet over the second sacrificial nanosheet.

8. The method of claim 7 further comprising, removing the first sacrificial nanosheet and the second sacrificial nanosheet, wherein the replacement gate stack fill spaces left by the first sacrificial nanosheet and the second sacrificial nanosheet.

9. The method of claim 1 further comprising, before the source/drain region is formed in the recess, forming a dielectric layer at a bottom of the recess.

10. A method comprising:
forming a first semiconductor nanostructure;
forming a second semiconductor nanostructure over the first semiconductor nanostructure;
forming a gate stack over the second semiconductor nanostructure;
etching portions of the first semiconductor nanostructure and the second semiconductor nanostructure on a side of the gate stack to form a source/drain recess; and
performing epitaxy processes to form a source/drain region in the source/drain recess, wherein the epitaxy processes comprise:
a first epitaxy process to form a first semiconductor layer using first process conditions, wherein the first semiconductor layer is free from dislocations therein; and
a second epitaxy process to form a second semiconductor layer using second process conditions different from the first process conditions, wherein the second semiconductor layer comprise dislocations therein.

11. The method of claim 10, wherein the first process conditions comprise a first wafer temperature, and the second process conditions comprise a second wafer temperature different from the first wafer temperature.

12. The method of claim 11, wherein the second wafer temperature is higher than the first wafer temperature.

13. The method of claim 10, wherein the first process conditions comprise a first flow rate of a silicon-containing precursor, and the second process conditions comprise a second flow rate of the silicon-containing precursor, and wherein the second flow rate is higher than the first flow rate.

14. The method of claim 10, wherein the first process conditions comprise a first partial pressure of a silicon-containing precursor, and the second process conditions comprise a second partial pressure of the silicon-containing precursor, and wherein the second partial pressure is higher than the first partial pressure.

15. The method of claim 10, wherein all of the dislocations in the source/drain region are spaced apart from all semiconductor nanosheets that are adjacent to the source/drain recess.

16. A method comprising:
forming a first semiconductor nanostructure;
forming a second semiconductor nanostructure over the first semiconductor nanostructure;
forming a gate stack over the second semiconductor nanostructure;
etching portions of the first semiconductor nanostructure and the second semiconductor nanostructure on a side of the gate stack to form a source/drain recess; and
forming a source/drain region in the source/drain recess, wherein the source/drain region is formed by processes comprising:
forming a first semiconductor layer free from dislocations therein; and
forming a second semiconductor layer comprising dislocations therein.

17. The method of claim 16, wherein the second semiconductor layer is continuously grown until the source/drain recess is fully filled.

18. The method of claim 16, wherein the first semiconductor layer is formed by processes comprising a plurality of cycles, each comprising:
depositing a layer of the first semiconductor layer; and
etching back the layer of the first semiconductor layer, until all dislocations in the layer of the first semiconductor layer are removed.

19. The method of claim 16, wherein the second semiconductor layer is grown at a higher deposition rate than the first semiconductor layer.

20. The method of claim 16, wherein the second semiconductor layer is grown at a higher wafer temperature than the first semiconductor layer.
